(19) United States
(12) Patent Application Publication
(10) Pub. No.: US 2008/0204064 A1
(43) Pub. Date: Aug. 28, 2008

(54) TEST SYSTEM AND HIGH VOLTAGE MEASUREMENT METHOD

(75) Inventors: Pyung-Moon Zhang, Yongin-si (KR); Jin-Yub Lee, Seocho-gu (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/034,878

(22) Filed: Feb. 21, 2008

(30) Foreign Application Priority Data
Feb. 27, 2007 (KR) 10-2007-0019796

(51) Int. Cl. G01R 31/26

(52) U.S. Cl. 324/765

(57) ABSTRACT

Provided are a test system and a related high voltage measurement method. The method includes applying an external voltage signal to one or more of a plurality of DUTs via the shared channel, comparing the external voltage signal with a high voltage signal internally generated by the one or more DUTs and generating a corresponding comparison result, and determining a voltage level for each respective high voltage signal in accordance with the comparison result.

### CROSS-REFERENCE TO RELATED APPLICATIONS

This U.S. non-provisional patent application claims priority under 35 U.S.C. §119 to Korean Patent Application No. 10-2007-0019796, filed on Feb. 27, 2007, the subject matter of which is hereby incorporated by reference.

### BACKGROUND OF THE INVENTION

1. Field of the Embodiments

The present invention relates to a test system, and more particularly, to a test system and a related high voltage measurement method.

2. Description of the Related Art

The testing of semiconductor memory devices typically involves the use of a memory tester. The memory tester measures signals related to certain performance parameters of the memory device. Such signals may be measured in terms of a direct current (DC) value, an alternating current (AC) value, or a functional indication (e.g., a signal transition from one state to another state).

Most contemporary memory testers (hereinafter generically referred to as a ‘test device’) include a computer or a similar computational platform running a test program that obtains and/or processes test data, as well as controls the overall flow of the testing process. Test devices generally include AC and DC measuring units capable of measuring, detecting, and/or providing the power voltages and other signals related to operate the memory device. Test devices also generally include a test pattern generator providing the control, address and/or data (C/A/D) signals necessary to operate the memory device. These C/A/D signals may be related to various commands also generated by the test device and applied to the memory device. In order to fully exercise the memory device being tested, the test device may alter the formats, order, etc., of the C/A/D signals using certain algorithms and/or test protocols. The operation of the test pattern generator may rely on a timing generator that generates certain signal waveforms associated with measured signals of the memory device.

Common DC testing involves the evaluation of memory device characteristics such as the stability of electrical wiring, the amount of current consumed during various operations, leakage current, etc. These characteristics and the related internal circuitry within the memory device are evaluated by applying one or more test input signals to one or more Input/Output (I/O) pins of the memory device and then detecting or measuring corresponding test output signals. The test input/output signals may be voltages or currents, and the I/O pins may include one or more specialized test pins.

Common AC testing involves the evaluation of other memory device characteristics such as data I/O transfer rates, data access time, etc. AC testing includes the definition and application of certain pulse signals to an I/O pin of the memory device. AC testing may evaluate the response of the memory device to a signal rise time, a signal fall time, a rising edge of a pulse signal, a falling edge of a pulse signal, a high logic level, a low logic level, a pulse width period, etc.

Functional testing uses a test pattern generator to input a test pattern to the memory device. A resulting output signal is then compared to an expected output pattern which may be generated by a test pattern generator. Circuitry internal to the memory device may be tested across a range of operating parameters by varying certain voltages applied to the memory device, and/or certain test patterns while simultaneously altering operating conditions, such as applied power voltage levels, pressure, clock signal characteristics, etc. In certain tests, a test pattern may replicate an address signal sequence selecting memory cells and writing test data to the selected memory cells, as well as related clock signals.

Figure (FIG.) 1 is a block diagram of a conventional test system 1000. Test system 1000 includes a test device 1100 and a plurality of devices under test (DUTs) 1200 to 1500. Test device 1100 is connected to the respective DUTs 1200 to 1500 via ‘m’ channels CH1 to CHm.

To reduce overall testing time, test system 1000 performs some tests in parallel. Thus, a “parallel test” is a test method that applies various test signals (e.g., driving signals, data signals, and power voltages) to a plurality of DUTs 1200 to 1500 in order to simultaneously test the plurality of DUTs 1200 to 1500.

For example, a high voltage measurement test applied to the plurality of DUTs 1200 to 1500 by the test system 1000 illustrated in FIG. 1 may be performed as follows. Test device 1100 assigns a measurement channel CHm for measuring the desired high voltage to each one of the plurality of DUTs 1200 to 1500. The remaining channels CH1 to CHm−1 are used to transfer other test signals (e.g., addresses, data, and related control signals).

In order to perform a high voltage measurement test on 64 DUTs, for example, test device 1100 would require 64 times the number of test channel(s) required to test a single DUT. However, the practical number of channels that may be connected to test device 1100 is limited. Thus, the number of DUT that may be tested in parallel is similarly limited.

### SUMMARY OF THE INVENTION

Embodiments of the invention provide a test system and a related high voltage measurement method capable of increasing the number of devices under test (DUTs) that may be simultaneously tested.

In one embodiment, the invention provides a method for measuring a high voltage signal in a test system including a test device connected to each one of a plurality of devices under test (DUTs) via a shared channel, the method comprising; applying an external voltage signal to a DUT within the plurality of DUTs via the shared channel, comparing the external voltage signal with a high voltage signal internally generated by the DUT and generating a corresponding comparison result, and determining a voltage level for the high voltage signal in accordance with the comparison result.

In another embodiment, the invention provides a method for measuring a high voltage signal in a test system including a test device connected to each one of a plurality of devices under test (DUTs) via a shared channel, the method comprising; simultaneously applying an external voltage signal to each one of the plurality of DUTs via the shared channel, for each one of the plurality of DUTs, comparing the external voltage signal with a high voltage signal internally generated by the respective DUT and generating a corresponding comparison result, and determining a respective voltage level for each high voltage signal associated with each one of the plurality of DUTs in accordance with the corresponding comparison result.

In another embodiment, the invention provides a test system comprising; a test device configured to generate an external voltage signal; and a plurality of devices under test (DUTs), wherein each one of the plurality of DUTs is configured to receive the external voltage signal from a shared channel connecting the test device to each one of the plurality of DUTs, and further configured to return output test data to the test device via a respective communications channel, and each one of the plurality of DUTs comprises a high voltage generator circuit configured to generate a high voltage signal, provide a comparison result indicating a voltage level relationship between the high voltage signal and the external voltage signal, and output the comparison result to the test device via a corresponding communication channel.

### BRIEF DESCRIPTION OF THE FIGURES

FIG. 1 is a block diagram of a conventional test system;

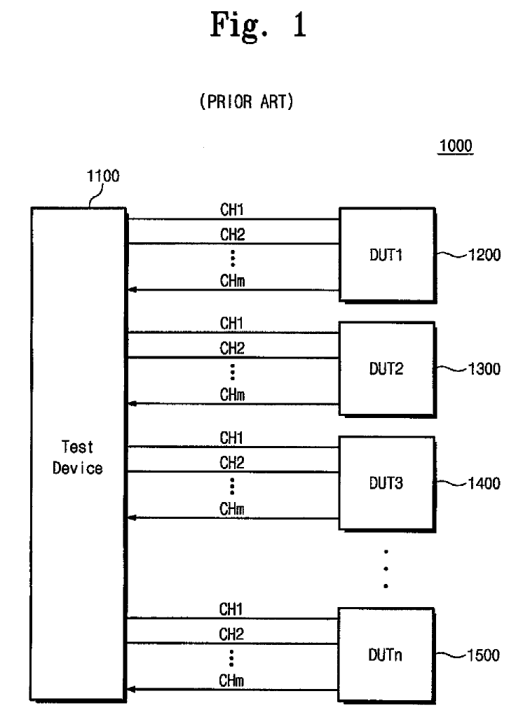

FIG. 2 is a block diagram of a test system according to an embodiment of the invention;

FIG. 3 is a block diagram according to one embodiment of the invention further illustrating a device under test (DUT) in relation to the test system of FIG. 2;

FIG. 4 is a diagram illustrating a sequential switching signal progression related to the testing of a plurality of DUTs;

FIG. 5 is a block diagram according to another embodiment of the invention further illustrating a device under test (DUT) in relation to the test system of FIG. 2;

FIG. 6 is a flowchart summarizing a high voltage measurement method related to the test system of FIG. 3;

FIG. 7 is a block diagram according to another embodiment of the invention further illustrating a device under test (DUT) in relation to the test system of FIG. 2;

FIG. 8 is a block diagram according to another embodiment of the invention further illustrating a device under test (DUT) in relation to the test system of FIG. 2; and

FIG. 9 is a flowchart summarizing a high voltage measurement method related to the test system in FIG. 5.

### DESCRIPTION OF EMBODIMENTS

Embodiments of the invention will now be described with reference to the accompanying drawings. The present invention may, however, be embodied in different forms and should not be construed as being limited to only the illustrated embodiments. Rather, the embodiments are presented as teaching examples.

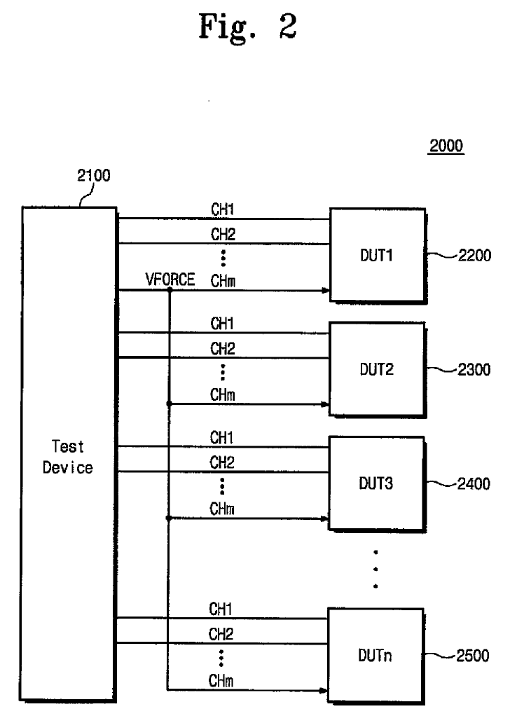

FIG. 2 is a general block diagram of a test system 2000 according to an embodiment of the invention. Referring to FIG. 2, test system 2000 comprises a test device 2100 and a plurality of devices under test (DUTs) 2200 to 2500. In the illustrated example, test system 2000 uses a shared channel CHm to measure a high voltage signal applied to each one of the plurality of DUTs 2200 to 2500. Other communications channels CH1 to CHm−1 are conventionally used to provide for address, data, and/or control signals.

In the illustrated embodiment of FIG. 2, the shared channel CHm is not used to directly measure the high voltage signal being applied to the plurality of DUTs 2200 to 2500. Rather, the shared channel CHm applies an external voltage signal VFORCE which is used to indirectly measure the high voltage signal. That is, in order to measure the high voltage signal applied to the plurality of DUTs 2200 to 2500, test device 2100 applies the external voltage signal VFORCE through the shared channel CHm to each one of the plurality of DUTs 2200 to 2500. Each one of the plurality of DUTs 2200 to 2500 then compares the level of the applied external voltage signal VFORCE with an internally generated high voltage signal and outputs the comparison result through one of the communications channels CH1 to CHm−1.

Test device 2100 is able to determine the actual voltage level of the high voltage signal for each one of the plurality of DUTs 2200 to 2500 using the provided comparison result. In certain embodiments of the invention, test system 2000 may sample a number of different Input/Output (I/O) pins to check whether the level of the external voltage signal VFORCE is equal to the level of the internally generated high voltage signal. In one embodiment, the external voltage signal VFORCE is applied with increasingly voltage level increments. However, other approaches may be taken, such as decreasing voltage increments, etc.

In such manners, test device 2100 is able to accurately determine respective voltage set points for each high voltage signal apparent at each one of the plurality of DUTs 2200 to 2500 relative to one or more defined value(s). One possible approach is explained below in some additional detail.

In this example the DUTs 2200 to 2500 are assumed to be NAND flash memory devices, and it is further assumed that test device 2100 applies an external voltage signal VFORCE with increasing increments (e.g., 8V, 8.1V, 8.2V, . . . ) to the plurality of DUTs 2200 to 2500 via the shared channel CHm. The plurality of DUTs 2200 to 2500 respond individually to the applied external voltage VFORCE and output comparison data accordingly. If the point at which the output comparison data for a first DUT 2200 toggles from one state to another (e.g., from a negative comparison to the positive comparison) occurs between 9.0 V and 9.1 V, then test device 2100 determines that the level of the high voltage signal associated with the first DUT 2200 is 9.1 V. In contrast, if the point at which the output comparison data for a second DUT 2300 toggles between 8.9 V and 9.0 V, test device 2100 determines that the level of the high voltage signal associated with the second DUT 2300 as 9.0 V.

Because test system 2000 according to an embodiment of the invention used a shared channel to measure relevant high voltage signals for a plurality of DUTs 2200 to 2500 the conventional constraint of available test pins is mitigated.

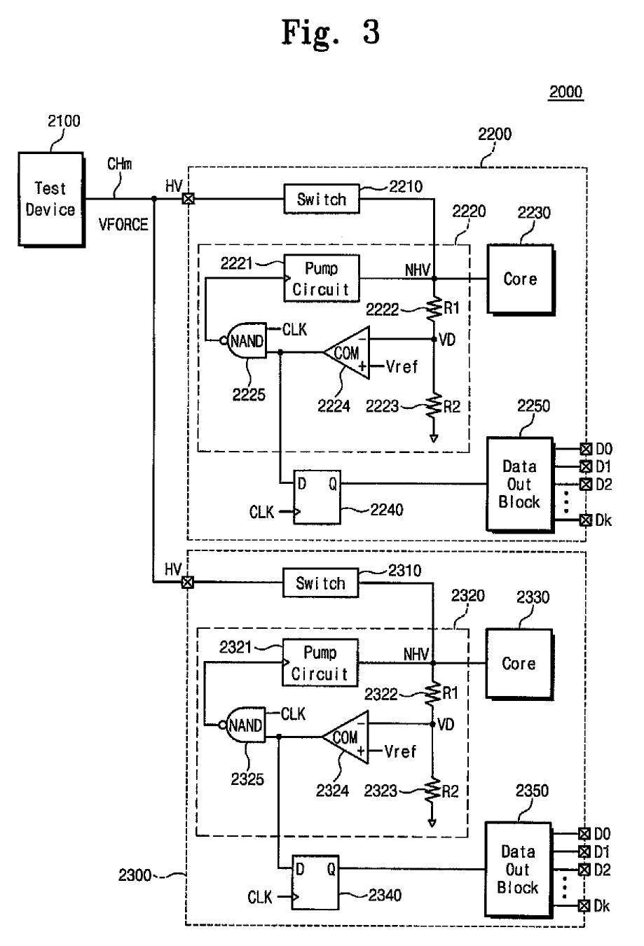

FIG. 3 is a circuit diagram further illustrating the first and second DUTs 2200 and 2300 within the plurality of similarly configured DUTS 2200 to 2500 of FIG. 2 according to an embodiment of the invention. Referring to FIG. 3, first DUT 2200 comprises a high voltage pin HV, a plurality of data output pads D0 to Dk, a switch 2210, a high voltage generating circuit 2220, a core 2230, a latch 2240 and a data output block 2250. First DUT 2200 according to the illustrated embodiment of FIG. 3, is assumed to compare an external voltage signal VFORCE applied with increasingly increments to an internally generated high voltage signal. First DUT 2200 then outputs a corresponding comparison result as a logically high/low signal in relation to the comparison.

Test device 2100 applies the external voltage signal VFORCE to first DUT 2200 via shared channel CHm connected to the high voltage pin HV. Test device 2100 then receives the corresponding comparison data output by first DUT 2200 from one of the plurality of data output pads D0 to Dk. In view of the received comparison result, test device 2100 is able to determine whether the level of the high voltage signal within first DUT 2200 falls within specification.

Within the illustrated embodiment of FIG. 3, switch 2210 responds to a switching signal SW and applies the voltage apparent at the high voltage pin HV to a voltage test node NHV. The switching signal SW may be applied via one of the communications channels CH1 to CHm−1 from test device 2100, and may in one embodiment of the invention be simultaneously transferred to each one of the plurality of DUTs 2200 to 2500. In another embodiment of the invention, the switching signal SW may be sequentially applied to the plurality of DUTs 2200 to 2500.

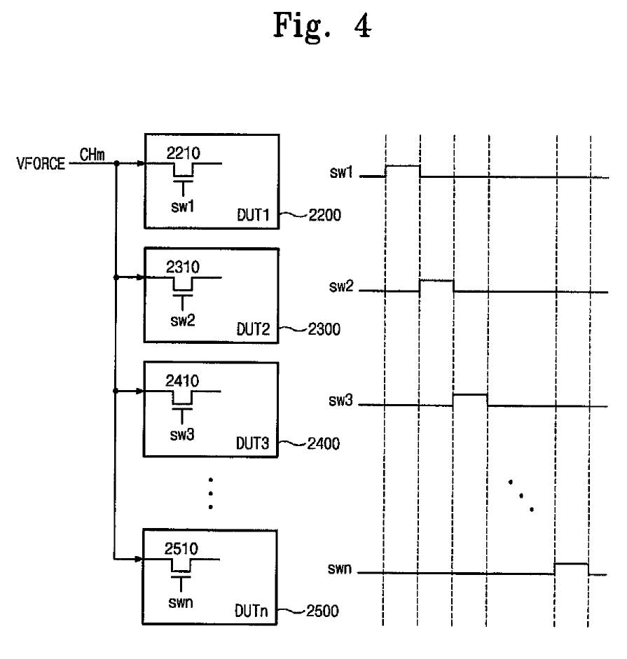

FIG. 4 is a block diagram illustrating the sequential application of the switching signal SW to each one of the plurality of DUTs 2200 to 2500. Referring to FIG. 4, respective switching signals SW1, SW2, . . . SWn are applied to each one of the plurality of DUTs 2200 to 2500 without temporal overlap. This type of sequential switching signal application may be preferred since the simultaneous opening of the respective switches 2210 to 2510 may excessively load the applied external voltage signal VFORCE causing an unacceptable drop in the applied DC voltage.

Test device 2100 may be used to control the sequential application of the switching signals SW1 . . . SWn. And in general, test device 2100 may control the application of respective or simultaneous switching signal(s) during a high voltage test period defined between an applied start command and an end command for each one of the plurality of DUTs 2200 to 2500.

Returning to FIG. 3, high voltage generating circuit 2220 generates the high voltage signal within DUT 2200 and this high voltage signal is apparent at the test node NHV. In the illustrated example, high voltage generating circuit 2220 comprises a pump circuit 2221, voltage dividing resistors 2222 and 2223, a comparator 2224, and a NAND gate 2225. The voltage dividing resistors voltages 2222 and 2223 distribute the high voltage signal (VHV) in relation to the test node NHV and a division voltage VD according to the following equation:

$$VD = \frac{R 2}{R 1 + R 2} \times V H V$$

Comparator 2224 compares the division voltage VD with a reference voltage Vref, and outputs a logical high or low value. For example, if the level of the division voltage VD is greater than the level of the reference voltage Vref, comparator 2224 outputs a low. On the other hand, if the level of the division voltage VD is less than the level of the reference voltage Vref, comparator 2224 outputs a high.

NAND gate 2225 receives the output of comparator 2224 and a reference clock CLK to perform a NAND operation. That is, the output value provided by comparator 2224 is converted synchronously with the reference clock CLK. When the output of comparator 2224 is low, NAND gate 2225 outputs a high in sync with the reference clock CLK and transfers this output to pump circuit 2221.

Pump circuit 2221 provides electrical charge to test node NHV in response to output of NAND gate 2225. That is, pump circuit 2221 is activated in response to a high provided by NAND gate 2225. The high voltage signal VHV apparent at the test node NHV increases with activation of pump circuit 2221.

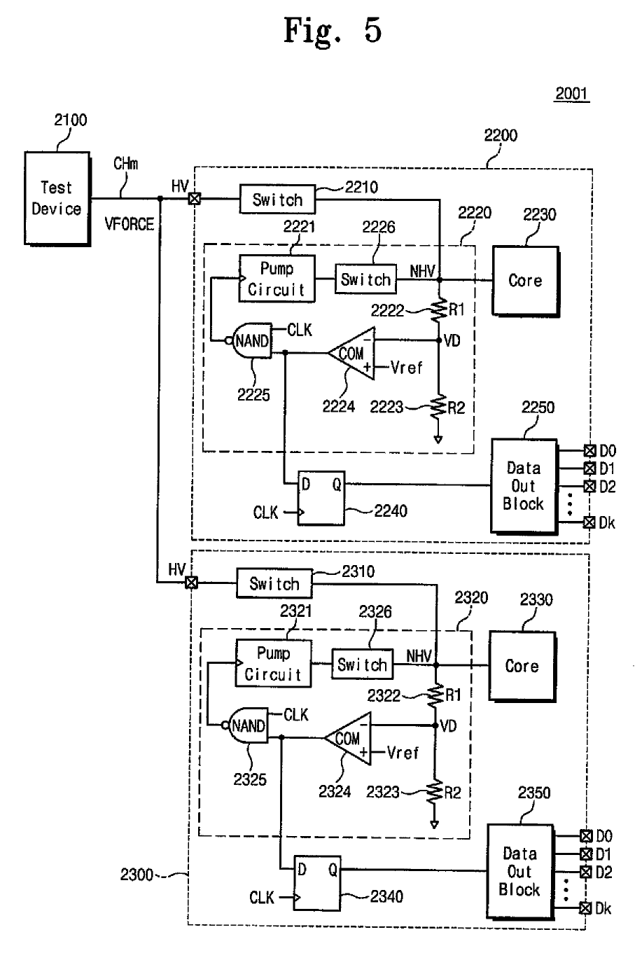

As test system 2000 measures the high voltage signal VHV, pump circuit 2221 may be activated or deactivated. This is because the voltage increase resulting from the application of the external voltage signal VFORCE to the test node NHV is more prominent than the voltage increase resulting from the operation of pump circuit 2221. However, this does not always have to be the case. As illustrated, for example, in the test system 2001 of FIG. 5, a second switch 2226 may be used to separate the test node NHV from pump circuit 2221. The second switch 2226 may be turned ON during period in which the high voltage signal VHV apparent at the test node NHV is being measured.

Once the high voltage signal VHV apparent at the test node NHV increases to a high voltage signal set point for first DUT 2200, the level of the division voltage VD becomes the same as the level of the reference voltage Vref. At this point, the output of comparator 2224 toggles from low to high. NAND gate 2225 receives the high from comparator 2224 in synch with the reference clock CLK, and outputs a low. Accordingly, pump circuit 2221 is deactivated in response to low provided by NAND gate 2225.

Latch 2240 latches the comparison result provided by comparator 2224 in sync with a clock CLK. This clock may be an internally generated clock signal and in one embodiment of the invention it may be generated in relation to an externally applied test mode signal provided by test device 2100.

Data output block 2250 receives and transfers the comparison result stored in latch 2240 to a designated one of the plurality of output pads D0 to Dk. This corresponding output pad may be connected to one of the communications channels CH1 to CHm−1.

In this manner, the first DUT 2200 receives the external voltage signal VFORCE which increases incrementally from test device 2100 via the shared channel CHm, and compares this signal to an internally generated high voltage signal VHV. First DUT 2200 then returns a comparison result to test device 2100 via a separate communications channel. Thus, test device 2100 determines the actual level of the high voltage signal VHV within the first DUT 2200 based on the derived comparison value.

In certain embodiments of the invention, test device 2100 includes a memory or latch circuit configured to store comparison results for each one of the plurality of DUTs 2200 to 2500.

In its operation, the illustrated test device 2100 incrementally increases the applied external voltage signal VFORCE, and may be used to simultaneously or sequentially perform high voltage signal measurement tests for the plurality of DUTs 2200 to 2500. When the measurement of a high voltage signal VHV for each respective one of the plurality of DUTs 2200 to 2500 is complete, the DUT need no longer receive the external voltage signal VFORCE. Accordingly, in certain embodiments of the invention, test device 2100 may include a selection and/or switching circuitry and related control mechanisms that exclude a DUT already tested from receiving application of the external voltage signal VFORCE.

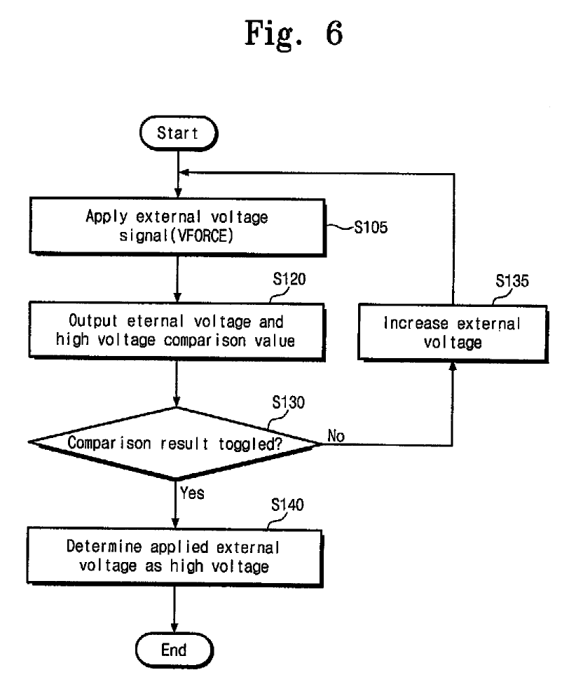

FIG. 6 is a flowchart summarizing a high voltage measurement method applicable to a test system such as the one illustrated in FIG. 3.

With reference to FIGS. 3 and 6, test device 2100 applies the external voltage signal VFORCE via the shared channel CHm to one or more of the plurality of DUTs 2200 to 2500 (S105). At this time, a high voltage test mode command (e.g., one or more test signals or a test command packet) may be separately communicated to the one or more DUTs. In response to the high voltage test mode command, the one or more DUTs may generate an internal clock CLK subsequently used in the high voltage testing. Also at this time, a switching signal SW may be applied to one or more respective switches 2210 to 2510.

The one or more DUTs 2200 to 2500 compare the level of the external voltage signal VFORCE to the level of the internally generated high voltage signal VHV and output a corresponding comparison result (S120).

Test device 2100 receives the comparison result for the one or more DUTs, stores the comparison results, and determines whether in response to the applied external voltage signal VFORCE at its current level the comparison result has logically toggled (S130).

If the comparison result has not toggled in its logical state, (S130=no), the external voltage signal VFORCE is incremented (S135) and the test method returns to the application of the external voltage signal VFORCE (S105). If, however, the comparison result toggles (S130=yes), then the current level of the external voltage signal VFORCE is determined to be equal to the internally generated high voltage signal for the one or more DUT (S140).

Once the internally generated high voltage signal for a particular one of the plurality of DUTs 2220 to 2500 is identified in relation to the external voltage signal VFORCE, it may be excluded from further application of the external voltage signal VFORCE by test device 2100. Once all internal high voltage signals for the entire plurality of DUTs have been determined, the test method performed within test system 2000 is complete.

In the foregoing embodiment, it is assumed that comparison results are stored in test device 2100, but this need not be the case. Instead, comparison results may be respectively stored in the DUTs 2200 to 2500.

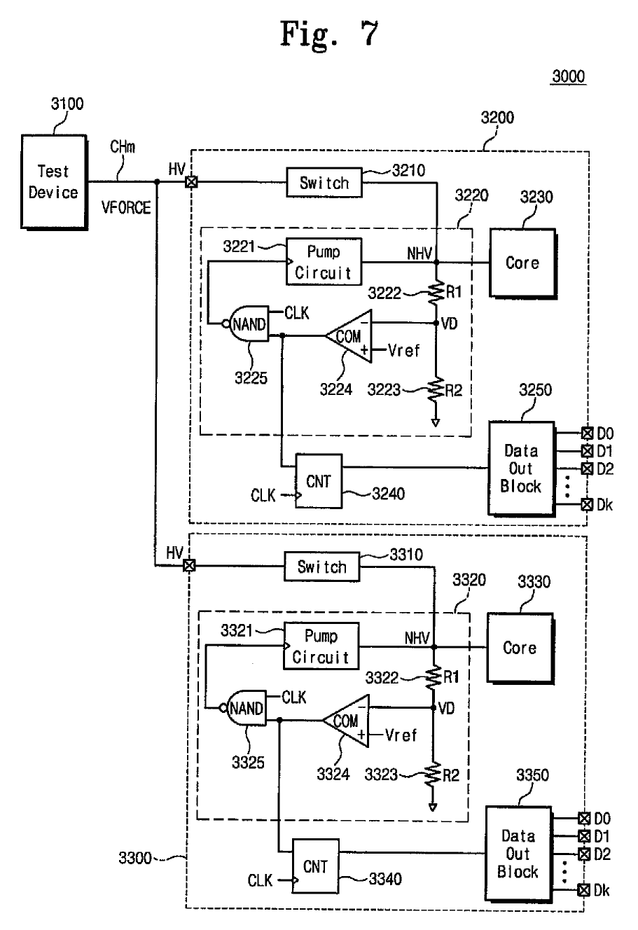

FIG. 7 is a circuit diagram of a test system 3000 according to another embodiment of the invention. Test system 3000 is assumed to include a test device 3100 and a plurality of DUTs 3200 to 3500, analogous to the configuration shown in FIG. 2. The configuration of test device 3100 and each one of the plurality of DUTs 3200 to 3500, including a first DUT 3200 and a second DUT 3300 shown in FIG. 7 is similar to that of test device 2100 and first DUT 2200 and second DUT 2300 of FIG. 3. However, each one of the plurality of DUTs 3200 to 3500 comprises respective counter circuits 3240 to 3350 adapted to store comparison results and replacing latches 2240 to 2540 of FIG. 3.

In operation, first counter 3240 in first DUT 3200 counts up in synchronization with the internal clock CLK when the comparison result provided by comparator 3224 is low, and stops counting up when the comparison result toggles to high. Here, the internal clock CLK may be generated as described above in relation to an externally applied high voltage test mode command communicated from test device 3100. First counter 3240 retains or stores a counted value for first DUT 3200.

Once the incremented application of the external voltage signal VFORCE reaches a defined maximum value, test device 3100 halts the high voltage measurement testing for the plurality of DUTs 3200 to 3500. Thereafter, test device 3100 may read the stored counter value from the respective counters 3224 to 3524 corresponding to the plurality of DUTs 3200 to 3500. In view of the respective counted values, test device 3100 may determine the actual respective levels of the high voltage signals internally generated by the DUTs 3200 to 3500.

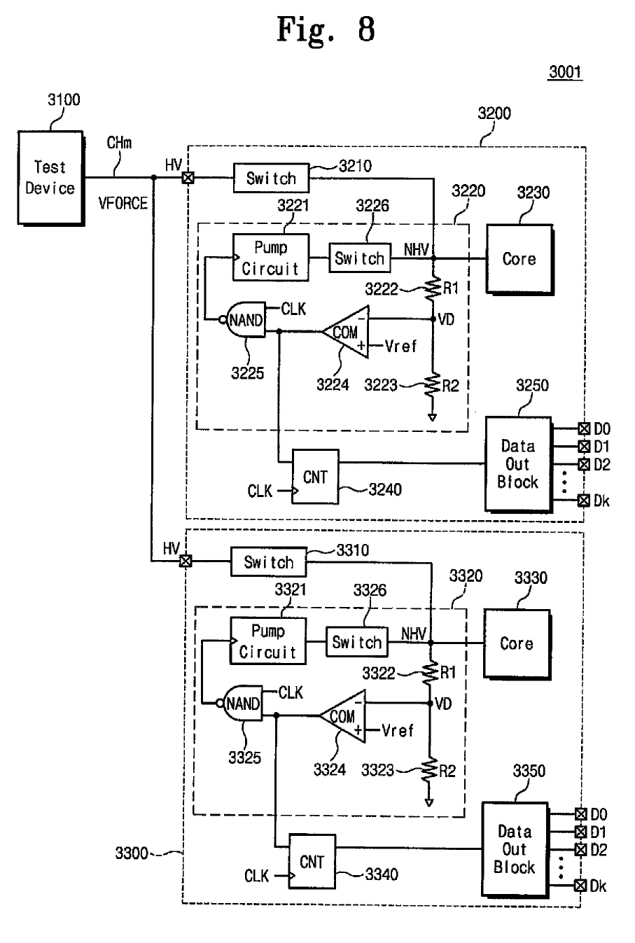

FIG. 8 is a circuit diagram of a test system according to another embodiment of the invention. Referring to FIG. 8, each one of the pluralities of DUT 3200 to 3500 further comprises a first switch 3210 to 3510 and a second switch 3226 to 3526 disposed between the respective pump circuits and test nodes NHV. Thus, in the manner explained in relation to the embodiment shown in FIG. 5, a second switch is used to isolate the test node during period in which the high voltage signal is being measured at the test node.

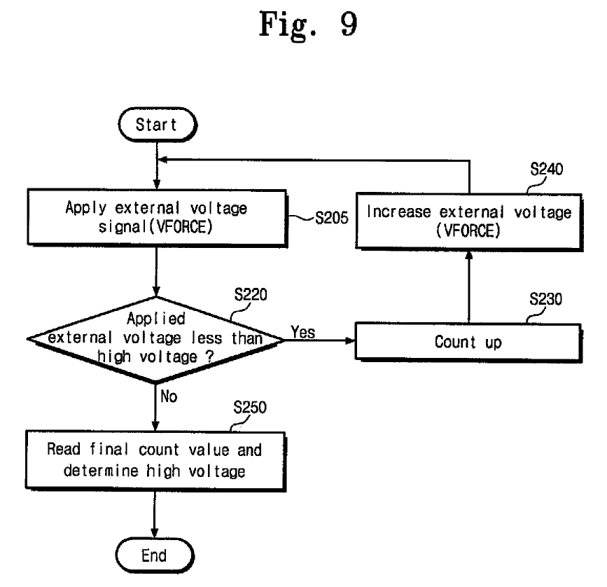

FIG. 9 is a flowchart summarizing a high voltage measurement method for the test system 3000 shown in FIG. 7 according to another embodiment of the invention.

First, test device 3100 develops and applies the external voltage signal VFORCE to one or more of DUTs 3200 to 3500 (S205). In response, the one ore more DUTs compare the applied external voltage signal to their high voltage signal and determine whether the external voltage signal is less then the high voltage signal (S220). So long as the applied external voltage signal VFORCE remains less then the high voltage signal, the counter circuit runs and counts up a counter value (S230). Further, the external voltage signal VFORCE is incremented upward, and the comparison loop repeated.

However, when the applied external voltage signal VFORCE rises to or above the high voltage signal, the counter circuit is stopped and at a final counter value. This final count value may be stored and read as an indication of the high voltage signal within the one or more DUTs (S250). In all other aspects, the measurement method of FIG. 9 may be deemed to be similar to the measurement method of FIG. 6, including possible variations, such as decrementing the value of the external voltage signal VFORCE, the storage of the final count value, etc.

As described in the context of the foregoing embodiments, a system and method testing a high voltage signal within a plurality of DUTs, such as semiconductor memory devices, may be rapidly applied to the plurality of DUTs despite the use of only a single shared channel to provide an external voltage signal to one or more of the plurality of DUTs.

The above-disclosed subject matter is to be considered illustrative, and not restrictive, and the appended claims are intended to cover all such modifications, enhancements, and other embodiments, which fall within the scope of the invention. Thus, to the maximum extent allowed by law, the scope of the invention is to be determined by the broadest permissible interpretation of the following claims and their equivalents.

What is claimed is:

1. A method for measuring a high voltage signal in a test system including a test device connected to each one of a plurality of devices under test (DUTs) via a shared channel, the method comprising:
applying an external voltage signal to a DUT within the plurality of DUTs via the shared channel;
comparing the external voltage signal with a high voltage signal internally generated by the DUT and generating a corresponding comparison result; and
determining a voltage level for the high voltage signal in accordance with the comparison result.

2. The method of claim 1, further comprising:
determining on the basis of the comparison result whether the external voltage signal is less than the voltage level of the high voltage signal; and
where the external voltage signal is less than the voltage level of the high voltage signal, incrementing the external voltage signal.

3. The method of claim 1, further comprising:
determining on the basis of the comparison result whether the external voltage signal is greater than the voltage level of the high voltage signal; and
where the external voltage signal is greater than the voltage level of the high voltage signal, decrementing the external voltage signal.

4. The method of claim 1, further comprising:
providing the comparison result from the DUT to the test device and storing the comparison result in the test device, wherein the test device determines the voltage level of the high voltage signal in relation to the stored comparison result.

5. The method of claim 4, wherein the comparison result is provided from the DUT to the test device via a communication channel separate from the shared channel.

6. The method of claim 1, wherein following the determination of the voltage level for the high voltage signal generated in the DUT,
applying the external voltage signal to another DUT within the plurality of DUTs via the shared channel;
comparing the external voltage signal with a high voltage signal internally generated by the another DUT and generating a corresponding comparison result; and
determining a voltage level for the high voltage signal in accordance with the comparison result.

7. The method of claim 6, wherein each one of the plurality of DUTs is sequentially tested by the test device.

8. A method for measuring a high voltage signal in a test system including a test device connected to each one of a plurality of devices under test (DUTs) via a shared channel, the method comprising:
simultaneously applying an external voltage signal to each one of the plurality of DUTs via the shared channel;
for each one of the plurality of DUTs, comparing the external voltage signal with a high voltage signal internally generated by the respective DUT and generating a corresponding comparison result; and
determining a respective voltage level for each high voltage signal associated with each one of the plurality of DUTs in accordance with the corresponding comparison result.

9. A test system comprising:
a test device configured to generate an external voltage signal; and
a plurality of devices under test (DUTs), wherein each one of the plurality of DUTs is configured to receive the external voltage signal from a shared channel connecting the test device to each one of the plurality of DUTs, and further configured to return output test data to the test device via a respective communications channel; and
each one of the plurality of DUTs comprises a high voltage generator circuit configured to generate a high voltage signal, provide a comparison result indicating a voltage level relationship between the high voltage signal and the external voltage signal, and output the comparison result to the test device via a corresponding communication channel.

10. The test system of claim 9, wherein each one of the plurality of DUTS further comprises:
a switch responsive to a switching signal to apply the external voltage signal to the high voltage generator.

11. The test system of claim 9, further comprising:
a latch receiving and storing the comparison result from the high voltage generator circuit; and
a data output block receiving the stored comparison result from the latch and providing the comparison result to the test device via the corresponding communication channel.

12. The test system of claim 9, wherein the plurality of DUTs simultaneously receives the external voltage signal.

13. The test system of claim 12, wherein the external voltage signal is incremented or decremented until the comparison result changes.

14. The test system of claim 10, wherein respective ones of the plurality of DUTs sequentially receive the external voltage signal by timed operation of the respective switches by corresponding switching signals.

15. The test system of claim 9, wherein the high voltage generator comprises:
a pump circuit generating the high voltage signal at a test node, wherein a voltage apparent at the test node is determined by a voltage divider and a corresponding division voltage;
a comparator circuit comparing the division voltage with a reference voltage to generate the comparison result;
a NAND gate receiving the comparison result and a reference clock and providing a synchronous version of the comparison result to activate/deactivate the pump circuit in accordance with gated version of the comparison result.

16. The test system of claim 15, further comprising:
a latch receiving and storing the comparison result; and
a data output block receiving the comparison result and providing the comparison result to the test device via a corresponding communication channel.

17. The test system of claim 15, further comprising:
a counter circuit receiving the comparison result and providing a running count value when the comparison result is in one state, but stopping the count value when the comparison result toggle from the one state to another state, wherein the count value when stopped is a final count value; and
a data output block receiving the final count value and providing the final count value to the test device via a corresponding communication channel.

18. The test system of claim 15, wherein each one of the plurality of DUTS further comprises:
a first switch responsive to a switching signal to apply the external voltage signal to the high voltage generator; and
wherein the high voltage generator further comprises a second switch disposed between the pump circuit and the test node.
